(19) United States
(12) Patent Application Publication
(10) Pub. No.: US 2006/0163571 A1
(43) Pub. Date: Jul. 27, 2006

(54) Test element group structures having 3 dimensional SRAM cell transistors

(75) Inventors: Bo-Tak Lim, Yongin-si (KR); Jong-Soo Seo, Hwaseong-si (KR)

Correspondence Address: F. CHAU & ASSOCIATES, LLC, 130 WOODBURY ROAD, WOODBURY, NY, 11797, US

(73) Assignee: Samsung Electronics Co., LTD., Suwon-si (KR)

(21) Appl. No.: 11/331,232

(22) Filed: Jan. 12, 2006

(30) Foreign Application Priority Data
Jan. 27, 2005 (KR) 10-2005-0007740

(51) Int. Cl. H01L 23/58

(52) U.S. Cl. 257/48

(57) ABSTRACT

A test element group structure having 3-dimensional SRAM cell transistors includes a bulk metal-oxide-semiconductor (MOS) transistor formed at a semiconductor substrate and a first interlayer insulating layer covering the bulk MOS transistor. A lower thin film transistor is disposed on the first interlayer insulating layer, and the lower thin film transistor is covered with a second interlayer insulating layer. An upper thin film transistor is disposed on the second interlayer insulating layer, and the upper thin film transistor is covered with a third interlayer insulating layer. A metal node plug is disposed to pass through the first to third interlayer insulating layers. The metal node plug electrically connects a first impurity region of the bulk MOS transistor, a first impurity region of the lower thin film transistor, and a first impurity region of the upper thin film transistor with each other.

### CROSS-REFERENCE TO RELATED APPLICATION

This application claims the benefit of Korean Patent Application No. 10-2005-0007740, filed on Jan. 27, 2005 in the Korean Intellectual Property Office, the disclosure of which is incorporated herein in its entirety by reference.

### BACKGROUND OF THE INVENTION

1. Field of the Invention

The present invention relates to semiconductor integrated circuit (IC) devices and, more particularly, to test element group (TEG) structures having 3-dimensional static random access memory (SRAM) cell transistors.

2. Description of Related Art

Semiconductor IC devices may be fabricated using unit processes such as a photo process, an etching process, a thin film deposition process, an ion implantation process or a diffusion process. Many semiconductor IC devices include internal circuits composed of discrete devices such as transistors, capacitors and resistors. The internal circuits may include a plurality of memory cells and peripheral circuits. Electrical characteristics of the semiconductor IC devices have a close relation to characteristics of the discrete devices.

It can be difficult to directly measure the electrical characteristics of the discrete devices constituting the internal circuits. This is because terminals of the discrete devices are connected to fine interconnections and the fine interconnections are covered with an insulating layer and a passivation layer. To measure the electrical characteristics of the discrete devices, probe pins are needed. The probe pins are contacted with the fine interconnections connected to input/output terminals of the discrete devices. Input and output signals may be respectively applied and measured through the probe pins. It may be difficult to physically connect the probe pins with selected ones of the fine interconnections. In addition, the probed interconnections may be physically damaged, degrading the reliability of the semiconductor IC device. To indirectly measure the electrical characteristics of the discrete devices, various test element groups corresponding to the discrete devices may be formed on a scribe lane between the semiconductor IC devices (e.g., main chips) or on a semiconductor substrate adjacent to the internal circuits in the main chip.

Examples of test element groups are disclosed in U.S. Pat. No. 5,949,090 to Iwasa et al., entitled “MOS TEG STRUCTURE”. According to Iwasa et al., a test element group shares active regions of the IC device formed on a main surface of a semiconductor substrate, wherein the test element group is adjacent to the IC device. In this case, MOS transistors of the TEG can be formed to have the close dimensions as MOS transistors of the IC device, since the TEG is formed to be adjacent to the IC device having a high pattern density.

To improve electrical characteristics and integration density of SRAM cells, a 3-dimensional complementary metal-oxide-semiconductor (CMOS) SRAM cell has been proposed. An integration density of the SRAM device employing the 3-dimensional CMOS SRAM is improved as compared to a typical SRAM device. Furthermore, the 3-dimensional CMOS SRAM cell may exhibit characteristics that are similar to the characteristics of a full CMOS SRAM cell composed of six bulk MOS transistors formed at the single crystal semiconductor substrate.

Therefore, a need exists for a TEG structure to evaluate the characteristics of the 3-dimensional CMOS SRAM cell.

### SUMMARY OF THE INVENTION

According to an embodiment of the present invention, a test element group (TEG) structure comprises a bulk MOS transistor formed at a semiconductor substrate and a first interlayer insulating layer covering the bulk MOS transistor. A lower thin film transistor is disposed on the first interlayer insulating layer, and the lower thin film transistor is covered with a second interlayer insulating layer. An upper thin film transistor is disposed on the second interlayer insulating layer, and the upper thin film transistor is covered with a third interlayer insulating layer. A first impurity region of the bulk MOS transistor, a first impurity region of the lower thin film transistor and a first impurity region of the upper thin film transistor are electrically connected to each other by a metal node plug passing through the first to third interlayer insulating layers.

The lower thin film transistor may be disposed to overlap the bulk MOS transistor, and the upper thin film transistor may be disposed to overlap the lower thin film transistor.

The lower thin film transistor and the upper thin film transistor may be single crystal thin film transistors.

The bulk MOS transistor and the upper thin film transistor may be NMOS transistors, and the lower thin film transistor may be a PMOS transistor.

The bulk MOS transistor and the lower thin film transistor may be NMOS transistors, and the upper thin film transistor may be a PMOS transistor.

A lower semiconductor node plug may be disposed in the first interlayer insulating layer, and the lower semiconductor node plug may be in contact with the first impurity region of the bulk MOS transistor and the first impurity region of the lower thin film transistor. In addition, an upper semiconductor node plug may be disposed in the second interlayer insulating layer, and the upper semiconductor node plug may be in contact with the first impurity region of the lower thin film transistor and the first impurity region of the upper thin film transistor. In this case, the metal node plug may be electrically connected to the lower semiconductor node plug and the upper semiconductor node plug in addition to the first impurity regions.

The lower semiconductor node plug and the upper semiconductor node plug may be single crystal semiconductor plugs, and the metal node plug may have ohmic contact with respect to both of a P type semiconductor and an N type semiconductor. The metal node plug is a tungsten plug.

The lower semiconductor node plug may have the same conductivity type as the first impurity region of the bulk MOS transistor.

The lower semiconductor node plug may have a different conductivity type from the first impurity region of the bulk MOS transistor.

The metal node plug and the third interlayer insulating layer may be covered with an upper interlayer insulating layer, and a plurality of pads may be disposed on the upper interlayer insulating layer. The plurality of pads may be electrically connected to terminals of the transistors through a plurality of interconnections disposed in the interlayer insulating layers, respectively. Each of the interconnections may include a conductive fuse.

According to an embodiment of the present invention, a TEG structure comprises a semiconductor substrate and a bulk MOS transistor formed at the semiconductor substrate. The bulk MOS transistor includes a first source region, a first drain region formed in the semiconductor substrate and a first gate electrode crossing over a channel region between the first source/drain regions. A first interlayer insulating layer is disposed on the substrate having the bulk MOS transistor. A lower semiconductor body is disposed on the first interlayer insulating layer, and a lower thin film transistor is disposed at the lower semiconductor body. The lower thin film transistor includes a second source region, a second drain region formed in the lower semiconductor body and a second gate electrode crossing over a channel region between the second source/drain regions. A second interlayer insulating layer is disposed on the substrate having the lower thin film transistor. An upper semiconductor body is disposed on the second interlayer insulating layer, and an upper thin film transistor is disposed at the upper semiconductor body. The upper thin film transistor includes a third source region, a third drain region formed in the upper semiconductor body and a third gate electrode crossing over a channel region between the third source/drain regions. A third interlayer insulating layer is disposed on the substrate having the upper thin film transistor. The first to third drain regions are in contact with a metal node plug passing through the first to third interlayer insulating layers.

### BRIEF DESCRIPTION OF THE DRAWINGS

The present invention will become more apparent by describing in detail exemplary embodiments thereof with reference to the attached drawings in which:

FIG. 1 is a schematic plan view illustrating a semiconductor chip having a test element group structure according to an embodiment of the present invention;

FIG. 2 is a block diagram having an equivalent circuit diagram of the test element group structure shown in FIG. 1;

FIG. 3 is a plan view illustrating a test element group structure according to an embodiment of the present invention;

FIG. 4A is a cross sectional view taken along line I-I′ of FIG. 3; and

FIG. 4B is a cross sectional view taken along line II-II′ of FIG. 3.

### DETAILED DESCRIPTION OF PREFERRED EMBODIMENTS

The present invention will now be described more fully with reference to the accompanying drawings, in which exemplary embodiments of the invention are shown. The invention may, however, be embodied in many different forms and should not be construed as being limited to embodiments set forth herein; rather, embodiments are provided so that this disclosure will be thorough and complete, and will fully convey the concept of the invention to those skilled in the art. In the drawings, the thicknesses of layers and regions are exaggerated for clarity. Like reference numerals denote like elements throughout the specification.

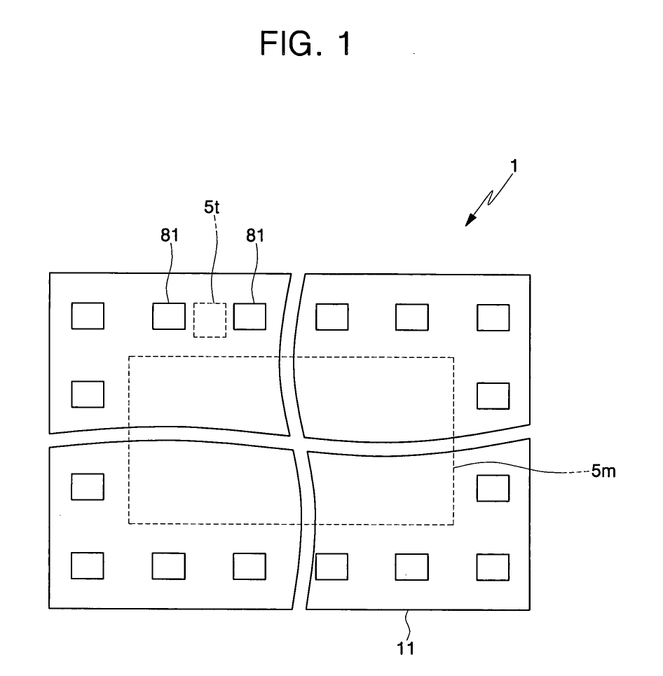

FIG. 1 is a schematic plan view illustrating a semiconductor chip 1 having a test element group structure 5t according to an embodiment of the present invention.

Referring to FIG. 1, the semiconductor chip 1 includes a plurality of pads 81 disposed adjacent to edges of a semiconductor substrate 11 having a rectangular shape and an internal circuit 5m, e.g., a main circuit formed on a central region of the semiconductor substrate 11. A test element group structure 5t is disposed on the semiconductor substrate 11, adjacent to the main circuit 5m (for example, on the semiconductor substrate 11 between the pads 81). The pads 81 may be disposed in a central portion of the semiconductor chip 1.

According to an embodiment of the present invention, the test element group structure 5t may be disposed on a scribe lane between the adjacent semiconductor chips 1, for example, on main chips.

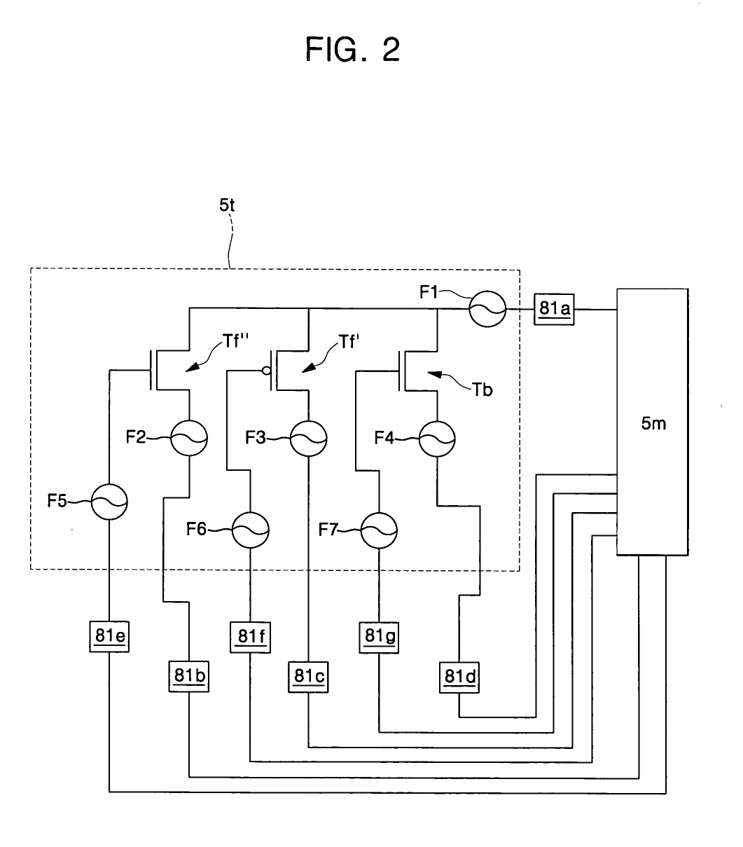

FIG. 2 is a schematic block diagram showing an equivalent circuit diagram of the test element group structure 5t of FIG. 1, pads, and internal circuit connected to the test element group structure 5t.

Referring to FIG. 2, the test element group structure 5t includes a bulk Metal-Oxide-Semiconductor (MOS) transistor Tb, a first thin film transistor Tf′ and a second thin film transistor Tf″. Drain regions of the second thin film transistor Tf″, the first thin film transistor Tf′ and the bulk MOS transistor Tb may be electrically connected to a node pad 81a through a first fuse F1. Source regions of the second thin film transistor Tf″, the first thin film transistor Tf′ and the bulk MOS transistor Tb may be electrically connected to first to third source pads 81b, 81c and 81d through second to fourth fuses F2, F3 and F4, respectively. Gate electrodes of the second thin film transistor Tf″, the first thin film transistor Tf′ and the bulk MOS transistor Tb may be electrically connected to first to third gate pads 81e, 81f and 81g through fifth to seventh fuses F5, F6 and F7, respectively. The pads 81a, 81b, 81c, 81d, 81e, 81f and 81g may be electrically connected to the internal circuit 5m shown in FIG. 1.

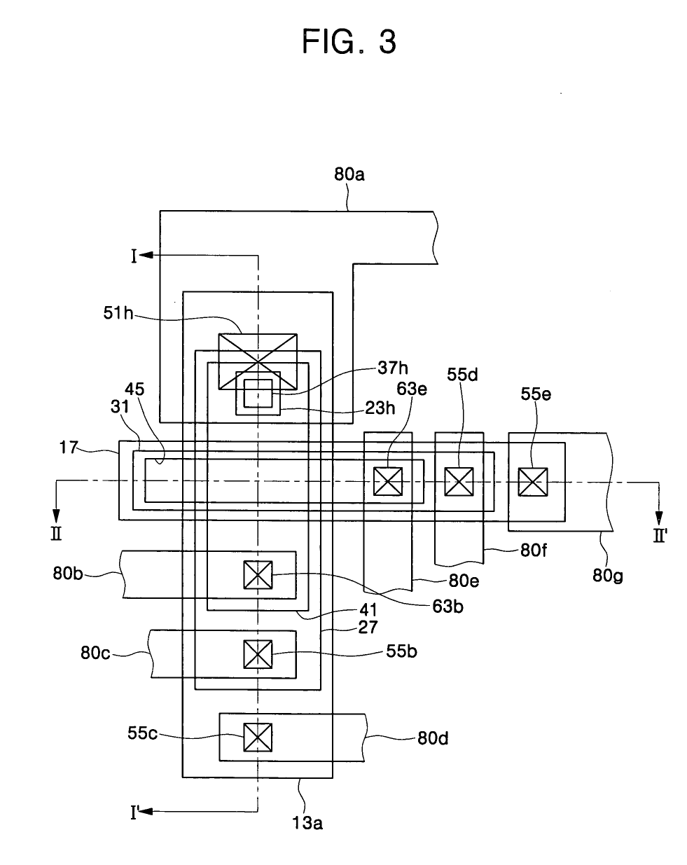

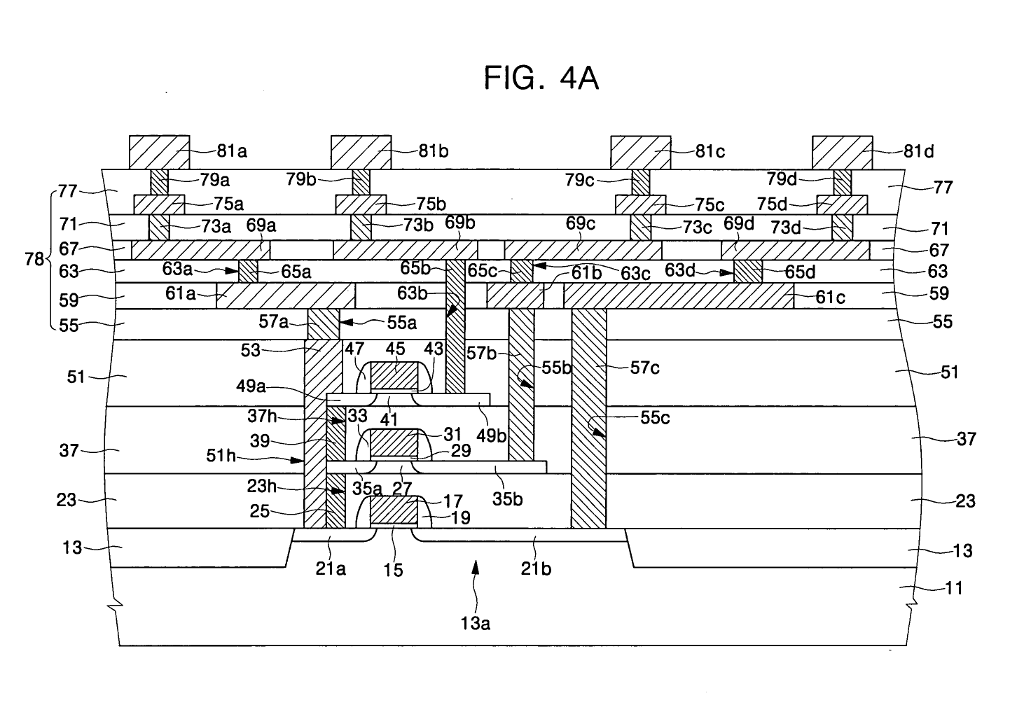

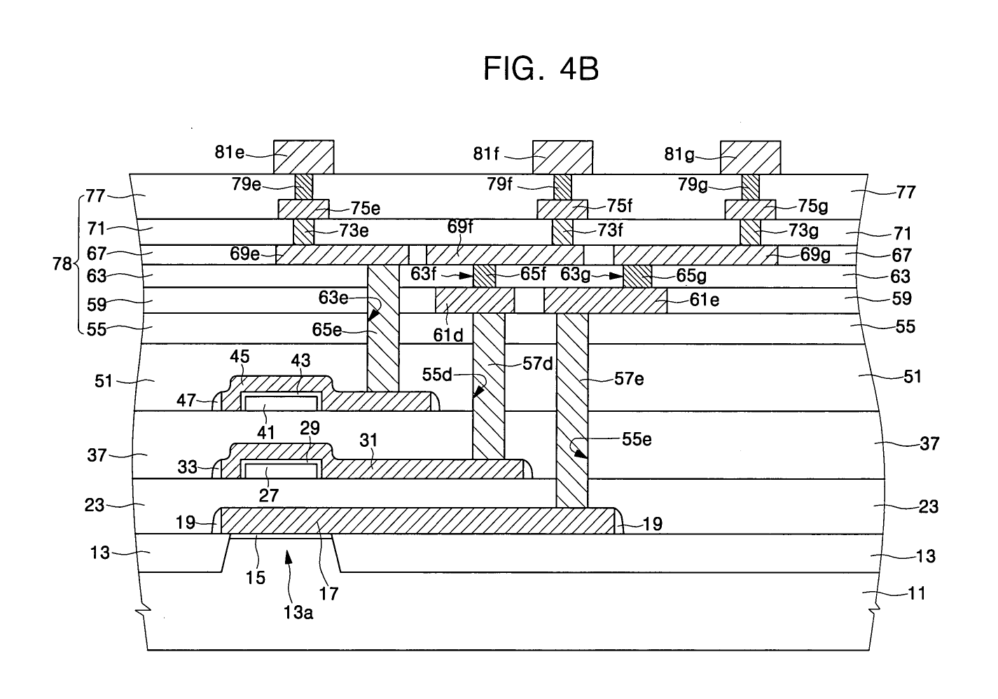

FIG. 3 is a plan view of the test element group structure 5t shown in FIG. 2. FIG. 4A is a cross sectional view taken along line I-I′ of FIG. 3, and FIG. 4B a cross sectional view taken along line II-II′ of FIG. 3. The test element group structure shown in FIGS. 3, 4A and 4B includes transistors employed in a 3-dimensional SRAM cell to have a structure suitable to indirectly evaluate electrical characteristics of the 3-dimensional SRAM cell. The present invention is not limited to the test element group structure of the 3-dimensional SRAM cell. For example, the test element group structure according to an embodiment of the present invention may be used as a test element group structure of semiconductor IC devices employing bulk MOS transistors formed at a semiconductor substrate or first and second thin film transistors sequentially staked on the bulk MOS transistors.

Referring to FIGS. 3, 4A and 4B, an isolation layer 13 is disposed in a predetermined region of the semiconductor substrate 11 to define an active region 13a. A pair of first impurity regions, including a first drain region 21a and a first source region 21b, are disposed in the active region and are spaced apart from each other. A first gate electrode 17 is disposed to cross over a channel region between the first drain region 21a and the first source region 21b. The first gate electrode 17 is insulated from the channel region by a gate insulating layer 15. A sidewall of the first gate electrode 17 may be covered with a first spacer 19. The first gate electrode 17, the first drain region 21a and the first source region 21b constitute a bulk MOS transistor (Tb of FIG. 2). The bulk MOS transistor may be a negative-channel MOS (NMOS) transistor.

A first interlayer insulating layer 23 is disposed on the substrate having the bulk MOS transistor. A lower semiconductor body 27 is disposed on the first interlayer insulating layer 23. A pair of second impurity regions, comprised of a second drain region 35a and a second source region 35b, are disposed in the lower semiconductor body 27. A second gate electrode 31 is disposed to cross over a channel region between the second drain region 35a and the second source region 35b. The second gate electrode 31 is insulated from the channel region by a gate insulating layer 29. A sidewall of the second gate electrode 31 may be covered with a second spacer 33. The second gate electrode 31, the second drain region 35a and the second source region 35b constitute a first thin film transistor, which is, a lower thin film transistor (Tf″ of FIG. 2). The lower thin film transistor may be an NMOS transistor or a PMOS transistor. The lower thin film transistor may be disposed to overlap with the bulk MOS transistor, as shown in the plan view of FIG. 3. The lower semiconductor body 27 may overlap with the active region 13a, and the second gate electrode 31 may overlap with the first gate electrode 17.

The first drain region 21a is exposed by a lower node contact hole 23h passing through the first interlayer insulating layer 23. The lower node contact hole 23h is filled with a lower semiconductor node plug 25. The lower semiconductor node plug 25 is in contact with a bottom surface of the lower semiconductor body 27. For example, the lower semiconductor node plug 25 may be in contact with the second drain region 35a. The lower semiconductor node plug 25 may be formed using a selective epitaxial growth technique that employs the first drain region 21a as a seed layer. In a case where the semiconductor substrate 11 is a single crystal semiconductor substrate, the lower semiconductor node plug 25 may also be a semiconductor plug having a single crystal structure.

The lower semiconductor body 27 may be an epitaxial semiconductor grown using the lower semiconductor node plug 25 as a seed layer. When the lower semiconductor node plug 25 is a single crystal semiconductor plug, the lower semiconductor body 27 may also have a single crystal structure. The lower semiconductor node plug 27 may have the same conductivity type as the first drain region 21a. Alternatively, the lower semiconductor node plug 27 may have a different conductivity type from the first drain region 21a. For example, when the first drain region 21a is an N type impurity region, the lower semiconductor node plug 25 may have an N type or a P type. According to an embodiment of the present invention, the lower semiconductor node plug 25 may be an intrinsic semiconductor plug, e.g., an undoped semiconductor plug.

A second interlayer insulating layer 37 is disposed on the substrate having the lower thin film transistor (e.g., the second gate electrode 31, the second drain region 35a and the second source region 35b). An upper semiconductor body 41 is disposed on the second interlayer insulating layer 37. A pair of third impurity regions, including a third drain region 49a and a third source region 49b, are disposed in the upper semiconductor body 41. A third gate electrode 45 is disposed to cross over a channel region between the third drain region 49a and the third source region 49b. The third gate electrode 45 is insulated from the channel region by a gate insulating layer 43. A sidewall of the third gate electrode 45 may be covered with a third spacer 47. The third gate electrode 45, the third drain region 49a and the third source region 49b constitute a second thin film transistor (Tf′ of FIG. 2), which is an upper thin film transistor.

In a case where the lower thin film transistor is a positive-channel MOS (PMOS) transistor, the upper thin film transistor may be an NMOS transistor. Alternatively, when the lower thin film transistor is an NMOS transistor, the upper thin film transistor may be a PMOS transistor. The upper thin film transistor may be disposed to overlap with the lower thin film transistor, as shown in the plan view of FIG. 3. The upper semiconductor body 41 may overlap with the lower semiconductor body 27, and the third gate electrode 45 may overlap with the second gate electrode 31.

The second drain region 35a is exposed by an upper node contact hole 37h passing through the second interlayer insulating layer 37. The upper node contact hole 37h is filled with an upper semiconductor node plug 39. The upper semiconductor node plug 39 is in contact with a bottom surface of the upper semiconductor body 41. For example, the upper semiconductor node plug 39 may be in contact with the third drain region 49a. The upper semiconductor node plug 39 may be formed using a selective epitaxial growth technique that employs the second drain region 35a as a seed layer. In a case where the lower semiconductor body 27 is a single crystal semiconductor body, the upper semiconductor node plug 39 may also be a semiconductor plug having a single crystal structure.

The upper semiconductor body 41 may be an epitaxial semiconductor grown using the upper semiconductor node plug 39 as a seed layer. When the upper semiconductor node plug 39 is a single crystal semiconductor plug, the upper semiconductor body 41 may also have a single crystal structure. The upper semiconductor node plug 39 may have the same conductivity type as the second drain region 35a. Alternatively, the upper semiconductor node plug 39 may have a different conductivity type from the second drain region 35a. According to an embodiment of the present invention, the upper semiconductor node plug 39 may be an intrinsic semiconductor plug.

A third interlayer insulating layer 51 is disposed on the substrate having the upper thin film transistor (e.g., the third gate electrode 45, the third drain region 49a and the third source region 49b). In a case where the lower semiconductor node plug 25 has the same conductivity type as the first drain region 21a, at least the second and third drain regions 35a and 49a may be exposed by a metal node contact hole 51h passing through the first to third interlayer insulating layers 23, 37 and 51, and the metal node contact hole 51h may be filled with a metal node plug 53. The metal node plug 53 may be in contact with at least the second and third drain regions 35a and 49a. In a case where the lower semiconductor node plug 25 has a different conductivity type from the first drain region 21a, the metal node plug 53 extends to be in contact with the first drain region 21a. The metal node plug 53 may be in contact with the semiconductor node plugs 25 and 39 in addition to the drain regions 21a, 35a and 49a. It is preferable that the metal node plug 53 is a metal layer having ohmic contact with respect to both of a P type semiconductor and an N type semiconductor. For example, the metal node plug 53 may be a tungsten plug.

A fourth interlayer insulating layer 55 is disposed on the substrate having the third interlayer insulating layer 51 and the metal node plug 53. The metal node plug 53 is exposed by a first lower interconnection contact hole 55a passing through the fourth interlayer insulating layer 55. The second source region 35b is exposed by a second lower interconnection contact hole 55b passing through the second to fourth interlayer insulating layers 37, 51 and 55. The first source region 21b is exposed by a third lower interconnection contact hole 55c passing through the first to fourth interlayer insulating layers 23, 37, 51 and 55.

Referring to FIG. 4B, the second gate electrode 31 is exposed by a fourth lower interconnection contact hole 55d passing through the second to fourth interlayer insulating layers 37, 51 and 55. The first gate electrode 17 is exposed by a fifth lower interconnection contact hole 55e passing through the first to fourth interlayer insulating layers 23, 37, 51 and 55.

The first to fifth lower interconnection contact holes 55a, 55b, 55c, 55d and 55e may be filled with first to fifth lower interconnection contact plugs 57a, 57b, 57c, 57d and 57e, respectively.

A fifth interlayer insulating layer 59 is disposed on the fourth interlayer insulating layer 55 and the lower interconnection contact plugs 57a, 57b, 57c, 57d and 57e. First to fifth lower interconnections 61a, 61b, 61c, 61d and 61e are disposed in the fifth interlayer insulating layer 59. The first to fifth lower interconnections 61a, 61b, 61c, 61d and 61e are electrically connected to the first to fifth lower interconnection contact plugs 57a, 57b, 57c, 57d and 57e, respectively.

A sixth interlayer insulating layer 63 is disposed on the fifth interlayer insulating layer 59 and the lower interconnections 61a, 61b, 61c, 61d and 61e. The first lower interconnection 61a is exposed by a first upper interconnection contact hole 63a passing through the sixth interlayer insulating layer 63. The third source region 49b is exposed by a second upper interconnection contact hole 63b passing through the third to sixth interlayer insulating layers 51, 55, 59 and 63. The second lower interconnection 61b is exposed by a third upper interconnection contact hole 63c passing through the sixth interlayer insulating layer 63. The third lower interconnection 61c is exposed by a fourth upper interconnection contact hole 63d passing through the sixth interlayer insulating layer 63.

Referring to FIG. 4B, the third gate electrode 45 is exposed by a fifth upper interconnection contact hole 63e passing through the third to sixth interlayer insulating layers 51, 55, 59 and 63. The fourth lower interconnection 61d is exposed by a sixth upper interconnection contact hole 63f passing through the sixth interlayer insulating layer 63. The fifth lower interconnection 61e is exposed by a seventh upper interconnection contact hole 63g passing through the sixth interlayer insulating layer 63.

The first to seventh upper interconnection contact holes 63a, 63b, 63c, 63d, 63e, 63f and 63g are filled with first to seventh upper interconnection contact plugs 65a, 65b, 65c, 65d, 65e, 65f and 65g, respectively.

A seventh interlayer insulating layer 67 is disposed on the sixth interlayer insulating layer 63 and the upper interconnection contact plugs 65a, 65b, 65c, 65d, 65e, 65f and 65g. First to seventh upper interconnections 69a, 69b, 69c, 69d, 69e, 69f and 69g are disposed in the seventh interlayer insulating layer 67. The first to seventh upper interconnections 69a, 69b, 69c, 69d, 69e, 69f and 69g are electrically connected to the first to seventh upper interconnection contact plugs 65a, 65b, 65c, 65d, 65e, 65f and 65g, respectively. The first to seventh upper interconnections 69a, 69b, 69c, 69d, 69e, 69f and 69g may correspond to conductive fuses F1, F2, F3, F4, F5, F6 and F7 of FIG. 2.

An eighth interlayer insulating layer 71 is disposed on the seventh interlayer insulating layer 67 and the upper interconnections 69a, 69b, 69c, 69d, 69e, 69f and 69g. First to seventh lower pads 75a, 75b, 75c, 75d, 75e, 75f and 75g are disposed on the eighth interlayer insulating layer 71. The first to seventh lower pads 75a, 75b, 75c, 75d, 75e, 75f and 75g are electrically connected to the first to seventh upper interconnections 69a, 69b, 69c, 69d, 69e, 69f and 69g through first to seventh lower pad contact plugs 73a, 73b, 73c, 73d, 73e, 73f and 73g passing through the eighth interlayer insulating layer 71, respectively.

The lower pads 75a, 75b, 75c, 75d, 75e, 75f and 75g and the eighth interlayer insulating layer 71 are covered with a ninth interlayer insulating layer 77. First to seventh upper pads 81a, 81b, 81c, 81d, 81e, 81f and 81g are disposed on the ninth interlayer insulating layer 77. The first to seventh upper pads 81a, 81b, 81c, 81d, 81e, 81f and 81g are electrically connected to the first to seventh lower pads 75a, 75b, 75c, 75d, 75e, 75f and 75g through first to seventh via contact plugs 79a, 79b, 79c, 79d, 79e, 79f and 79g passing through the ninth interlayer insulating layer 77, respectively. The fourth to ninth interlayer insulating layers 55, 59, 63, 67, 71 and 77 constitute an upper interlayer insulating layer 78.

The first upper pad 81a corresponds to a node pad electrically connected to the first to third drain regions 21a, 35a and 49a through a node interconnection (80a of FIG. 3) disposed in the upper interlayer insulating layer 78. The second upper pad 81b corresponds to a third source pad electrically connected to the third source region 49b through a third source interconnection (80b of FIG. 3) disposed in the upper interlayer insulating layer 78 and the third interlayer insulating layer 51. The third upper pad 81c corresponds to a second source pad electrically connected to the second source region 35b through a second source interconnection (80c of FIG. 3) disposed in the upper interlayer insulating layer 78, the second interlayer insulating layer 37 and the third interlayer insulating layer 51. The fourth upper pad 81d corresponds to a first source pad electrically connected to the first source region 21b through a first source interconnection (80d of FIG. 3) disposed in the upper interlayer insulating layer 78, the first interlayer insulating layer 23, the second interlayer insulating layer 37 and the third interlayer insulating layer 51.

The fifth upper pad 81e corresponds to a third gate pad electrically connected to the third gate electrode 45 through a third gate interconnection (80e of FIG. 3) disposed in the upper interlayer insulating layer 78 and the third interlayer insulating layer 51. The sixth upper pad 81f corresponds to a second gate pad electrically connected to the second gate electrode 31 through a second gate interconnection (80f of FIG. 3) disposed in the upper interlayer insulating layer 78, the second interlayer insulating layer 37 and the third interlayer insulating layer 51. The seventh upper pad 81g corresponds to a first gate pad electrically connected to the first gate electrode 17 through a first gate interconnection (80g of FIG. 3) disposed in the upper interlayer insulating layer 78, the first interlayer insulating layer 23, the second interlayer insulating layer 37 and the third interlayer insulating layer 51.

The node interconnection 80a is a multi-layered interconnection including the first upper interconnection 69a, e.g., the first fuse F1, and the third source interconnection 80b may be a multi-layered interconnection including the second upper interconnection 69b, e.g., the second fuse F2. The second source interconnection 80c is a multi-layered interconnection including the third upper interconnection 69c, e.g., the third fuse F3, and the first source interconnection 80d is a multi-layered interconnection including the fourth upper interconnection 69d, e.g., the fourth fuse F4. The third gate interconnection 80e is a multi-layered interconnection including the fifth upper interconnection 69e, e.g., the fifth fuse F5, and the second gate interconnection 80f is a multi-layered interconnection including the sixth upper interconnection 69f, e.g., the sixth fuse F6. The first gate interconnection 80g is a multi-layered interconnection including the seventh upper interconnection 69g, e.g., the seventh fuse F7.

In a case where the aforementioned test element group structure 5t is fabricated to share the pads in the main chip as shown in FIG. 1, electrical characteristics of the transistors of the test element group structure 5t are measured, and an electrical die sorting (hereinafter, referred to as “EDS”) test is performed to evaluate whether the internal circuit (5m of FIG. 1) of the main chip has desired electrical characteristics or not. The EDS test may be performed using alternating current (AC) signals as well as direct current (DC) signals. The EDS test may include a DC test and an AC test. When the EDS test, and more particularly, the AC test is performed, the test element group structure 5t connected to the pads 81a, 81b, 81c, 81d, 81e, 81f and 81g may affect the electrical characteristics of the internal circuit. Therefore, the test element group structure 5t can be electrically isolated from the pads 81a, 81b, 81c, 81d, 81e, 81f and 81g by cutting the fuses (e.g., the first to seventh upper interconnections 69a, 69b, 69c, 69d, 69e, 69f and 69g) using a laser technique prior to the EDS test.

According to an embodiment of the present invention, a test element group structure, which is capable of measuring electrical characteristics of transistors of a 3-dimensional SRAM cell, enables electrical data to be obtained as needed to evaluate characteristics of the 3-dimensional SRAM cell.

What is claimed is:

1. A test element group structure comprising:
a bulk metal-oxide-semiconductor (MOS) transistor formed at a semiconductor substrate;
a first interlayer insulating layer covering the bulk MOS transistor;
a lower thin film transistor formed on the first interlayer insulating layer;
a second interlayer insulating layer covering the lower thin film transistor;
an upper thin film transistor formed on the second interlayer insulating layer;
a third interlayer insulating layer covering the upper thin film transistor; and
a metal node plug passing through the first to third interlayer insulating layers to electrically connect a first impurity region of the bulk MOS transistor, a first impurity region of the lower thin film transistor; and a first impurity region of the upper thin film transistor with each other.

2. The test element group structure according to claim 1, wherein the lower thin film transistor is disposed to overlap the bulk MOS transistor, and the upper thin film transistor is disposed to overlap the lower thin film transistor.

3. The test element group structure according to claim 1, wherein the lower thin film transistor and the upper thin film transistor are single crystal thin film transistors.

4. The test element group structure according to claim 1, wherein the bulk MOS transistor and the upper thin film transistor are negative-channel MOS transistors, and the lower thin film transistor is a positive-channel MOS transistor.

5. The test element group structure according to claim 1, wherein the bulk MOS transistor and the lower thin film transistor are negative-channel MOS transistors, and the upper thin film transistor is a positive-channel MOS transistor.

6. The test element group structure according to claim 1, further comprising:
a lower semiconductor node plug disposed in the first interlayer insulating layer to be in contact with the first impurity region of the bulk MOS transistor and the first impurity region of the lower thin film transistor; and
an upper semiconductor node plug disposed in the second interlayer insulating layer to be in contact with the first impurity of the lower thin film transistor and the first impurity region of the upper thin film transistor,
wherein the metal node plug is electrically connected to the lower semiconductor node plug and the upper semiconductor node plug.

7. The test element group structure according to claim 6, wherein the lower semiconductor node plug and the upper semiconductor node plug are single crystal semiconductor plugs, and the metal node plug has ohmic contact with respect to both of a P type semiconductor and an N type semiconductor.

8. The test element group structure according to claim 7, wherein the metal node plug is a tungsten plug.

9. The test element group structure according to claim 1, wherein the lower semiconductor node plug has a conductivity type of the first impurity region of the bulk MOS transistor.

10. The test element group structure according to claim 1, wherein the lower semiconductor node plug has a different conductivity type from the first impurity region of the bulk MOS transistor.

11. The test element group structure according to claim 1, further comprising:
an upper interlayer insulating layer covering the metal node plug and the third interlayer insulating layer;
a plurality of pads disposed on the upper interlayer insulating; and
a plurality of interconnections disposed in interlayer insulating layers to electrically connect the plurality of pads with terminals of the transistors respectively.

12. The test element group structure according to claim 11, wherein each of the interconnections includes a conductive fuse.

13. A test element group structure comprising:
a semiconductor substrate;
a bulk metal-oxide-semiconductor (MOS) transistor including a first source region, a first drain region formed in the semiconductor substrate and a first gate electrode crossing over a channel region between the first source region and the first drain region;
a first interlayer insulating layer disposed on the substrate having the bulk MOS transistor;
a lower semiconductor body disposed on the first interlayer insulating layer;
a lower thin film transistor including a second source region, a second drain region formed in the lower semiconductor body and a second gate electrode crossing over a channel region between the second source region and the second drain region;
a second interlayer insulating layer disposed on the substrate having the lower thin film transistor;
an upper semiconductor body disposed on the second interlayer insulating layer;
an upper thin film transistor including a third source region, a third drain region formed in the upper semiconductor body and a third gate electrode crossing over a channel region between the third source region and the third drain region;
a third interlayer insulating layer disposed on the substrate having the upper thin film transistor; and
a metal node plug passing through the first to third interlayer insulating layers to be in contact with the first to third drain regions.

14. The test element group structure according to claim 13, wherein the lower thin film transistor is disposed to overlap the bulk MOS transistor, and the upper thin film transistor is disposed to overlap the lower thin film transistor.

15. The test element group structure according to claim 13, further comprising:
a lower semiconductor node plug disposed in the first interlayer insulating layer to be in contact with the first drain region and the lower semiconductor body; and
an upper semiconductor node plug disposed in the second interlayer insulating layer to be in contact with the second drain region and the upper semiconductor body,
wherein the metal node plug is in contact with the lower semiconductor node plug and the upper semiconductor node plug.

16. The test element group structure according to claim 15, wherein the lower semiconductor node plug has a conductivity type of the first drain region.

17. The test element group structure according to claim 15, wherein the lower semiconductor node plug has a different conductivity type from the first drain region.

18. The test element group structure according to claim 15, wherein the lower semiconductor node plug and the upper semiconductor node plug are single crystal semiconductor plugs.

19. The test element group structure according to claim 18, wherein the lower semiconductor body and the upper semiconductor body are single crystal semiconductor bodies.

20. The test element group structure according to claim 13, wherein the bulk MOS transistor and the upper thin film transistor are negative-channel MOS transistors, and the lower thin film transistor is a positive-channel MOS transistor.

21. The test element group structure according to claim 13, wherein the bulk MOS transistor and the lower thin film transistor are negative-channel MOS transistors, and the upper thin film transistor is a positive-channel transistor.

22. The test element group structure according to claim 13, wherein the metal node plug is a metal plug having ohmic contact with respect to both of a type semiconductor and an N type semiconductor.

23. The test element group structure according to claim 22, wherein the metal plug is a tungsten plug.

24. The test element group structure according to claim 13, further comprising:
an upper interlayer insulating layer covering the metal node plug and the third interlayer insulating layer;
a node pad, first to third source pads, and first to third gate pads disposed on the upper interlayer insulating layer;
a node interconnection disposed in the upper interlayer insulating layer to electrically connect the node pad to the metal node plug;
a first source interconnection and a first gate interconnection disposed in the upper interlayer insulating layer and the first to third interlayer insulating layers to electrically connect the first source region and the first gate electrode with the first source pad and the first gate pad respectively;
a second source interconnection and a second gate interconnection disposed in the upper interlayer insulating layer, the second interlayer insulating layer and the third interlayer insulating layer to electrically connect the second source region and the second gate electrode with the second source pad and the second gate pad respectively; and
a third source interconnection and a third gate interconnection disposed in the upper interlayer insulating layer and the third interlayer insulating layer to electrically connect the third source region and the third gate electrode with the third source pad and the third gate pad respectively.

25. The test element group structure according to claim 24, wherein each of the node interconnection, the first to third source interconnections, and the first to third gate interconnections include a conductive fuse.
